(19) United States
(12) Patent Application Publication
(10) Pub. No.: US 2009/0057914 A1
(43) Pub. Date: Mar. 5, 2009

(54) MULTIPLE CHIP SEMICONDUCTOR DEVICE

(75) Inventors: Klaus Dieter McDonald-Maier, Essex (GB); Andrew Brian Thomas Hopkins, Kent (GB)

Correspondence Address: BLAKELY SOKOLOFF TAYLOR & ZAFMAN LLP, 1279 OAKMEAD PARKWAY, SUNNYVALE, CA, 94085-4040, US

(73) Assignee: UNIVERSITY OF KENT, Kent (GB)

(21) Appl. No.: 11/658,487

(22) PCT Filed: Jul. 22, 2005
(86) PCT No.: PCT/GB2005/002881

§ 371 Date: Oct. 8, 2008

(30) Foreign Application Priority Data
Jul. 30, 2004 (GB) 0417059.3

(51) Int. Cl. H01L 23/50; H01L 21/60

(52) U.S. Cl. 257/777; 438/109; 257/786; 257/E23.079; 257/E21.506

(57) ABSTRACT

A semiconductor device has first and second semiconductor chips comprising electronic circuit elements located at an inner part of the chip and first connection terminals located on an upper surface of the inner part of the chip. One of the chips has second connection terminals located at a peripheral part of the chip. The first and second semiconductor chips are mounted one on top of the other to form the device connected together by the first connection terminals of the first and second semiconductor chips, and wherein the second connection terminals of the first semiconductor chip provide external connections to the device. The invention enables SoC resources to be increased based on the System-in-Package (SiP) approach by duplication identical chip components into a single package.

### FIELD OF THE INVENTION

This invention relates to semiconductor devices, particularly devices comprising multiple chips with an inter system chip communication interface.

### BACKGROUND OF THE INVENTION

A system chip also known as a System-on-Chip (SoC) and is a semiconductor chip assembly that includes multiple digital and/or analogue circuits such that a significant part of a system's active components are placed on the chip. A SoC is a single system chip containing processing resources, memory resources and often peripheral units or similar which can include analogue or digital circuits. In some realisations SoCs are equivalent to a microcontroller but tend to be larger.

In the past, there has been a need to integrate circuits into a system chip for which the chosen underlying digital or mixed signal semiconductor integration process was unsuitable. This problem was avoided by integrating each different type of circuit into system chips produced with a suitable technology for that circuit type. These different technology circuits could then be attached together using a bonding means such as flip-chip bonding or wire bonding to create a multi-chip module, also known as a System-in-Package (SiP), as the system is contained within a semiconductor device package rather than on a single chip.

A second common motivation for creating multi-chip modules is for high performance applications such as desktop computers where it is not possible to integrate the desired quantity of circuits on a single system chip. In this high performance application it is desirable to integrate part of the system on one chip and another part of the system on a second chip and then attach the two chips together using a bonding means. The method increases the number of circuits that can be integrated within the device packaging. The two or more system chips would often be produced in the same integration technology but contain different circuits.

Integration is now much higher in density than before, and continues to develop such that more circuits can be integrated within a given area with each successive integration technology generation. This removes the need to place the resources of a system in multiple chips produced using the same technology as the complete system can be integrated in a single chip to form a SoC. SoCs now prevail in almost all embedded computing applications as they are low cost to produce whereas the cost of a mass produced SiP is prohibitive in all but the highest performance applications. As new integration technology generations are developed with the ability to integrate more circuits within a given area the cost of the manufacturing equipment including the circuit layout masks is also increasing. Current 130 nm process masks cost about $250,000 whereas the new 90 nm masks cost about $1 Million. The next generation masks will be even more expensive and will increase as feature sizes/transistor sizes reduce.

For some low production quantity System-on-Chip (SoC) applications it desirable to have more of a given resource than used in the SoC developed for a high production unit count application for which the cost of producing a dedicated SoC has been found acceptable. For the low production quantity application or for a prototype unit the cost of a dedicated mask set may not be acceptable, furthermore the cost of designing a dedicated SoC may also be prohibitive. For applications requiring only a small number of units the most advanced and more integrated technologies are becoming too costly forcing the system designer to use either multiple or non-ideal existing commercial SoCs, a programmable logic device such as a field programmable gate array, or a custom SoC using a less advanced technology. All of these solutions result in reduced performance. Furthermore, custom SoCs and the configuration of programmable logic devices still incur significant design effort which is expensive.

For low production quantity aerospace and military prototypes the required extra resources may be extra processing, extra memory and extra peripherals. Such applications involve producing prototypes for systems that will not enter production until a few (3 to 10) years time, by which time resources in commercial SoCs will be greater in number and lower in cost due to the advancement of technology. Other applications requiring SoC resource extension are development parts. Development parts are required to emulate the functionality and behaviour of the production part while also providing additional resources for debugging and calibration purposes. Examples of development resources include memories for trace and calibration, increased trigger and trace qualification resources, communication paths to carry the debug trace data and peripherals to send the data off-chip or manage the processing of development related data.

There is therefore need for a method that allows a SoC or SiP to be produced that has a low fixed production cost, incurs almost no reduction in performance and does not require excessive further design effort.

### SUMMARY, OF THE INVENTION

According to the invention, there is provided a semiconductor device comprising:

a first semiconductor chip comprising electronic circuit elements located at an inner part of the chip, first connection terminals located on an upper surface of the inner part of the chip and second connection terminals located at a peripheral part of the chip; and

a second semiconductor chip comprising electronic circuit elements corresponding to those of the first semiconductor chip, and first connection terminals located on an upper surface of the chip corresponding to the first connection terminals of the first semiconductor chip,

wherein the first and second semiconductor chips are mounted one on top of the other to form the device, connected together by the first connection terminals of the first and second semiconductor chips, and wherein the second connection terminals of the first semiconductor chip provide external connections to the device.

The invention enables SoC resources to be increased based on the System-in-Package (SiP) approach as described above. The invention duplicates identical chip components into a single package, and thus uses circuits integrated into a high production count SoC design. The duplication enables the resources of the same SoC design such that a SiP is realised having more resources and circuits than the original design.

This is done by providing an interface arrangement within the SoC to reconfigure its interconnection system so that its resources can be accessed by another chip, attached using flip-clip bonding or similar.

If flip chip bonding is used, it will use pads placed in the top metal layer of each chip produced. These bonding pads are placed within the SoCs main periphery of bonding pads, which are normally used to connect it to the device package. Thus, when the SoC is flipped upside down its bonding pads for input align with the output pads of a second copy of the same SoC and vice versa for the flipped chip's outputs.

The placement of a flipped chip on top of a second chip would normally obscure the main peripheral ring of bonding pads of both chips, preventing conventional wire bonding to the package. This problem is overcome by removing the peripheral ring of bonding pads on one copy of the chip using conventional system chip cutting methods, and then using flip-chip bonding or similar to attach the remaining centre part of the chip containing the system circuits to another complete copy of the circuit.

The electrical connections made by bonding can include power and clock signals via the interface with the second copy of the chip. The interface circuits placed in each chip may optionally include configurable circuits to make accesses made to resources located in the same chip as the accessing unit have the same behaviour as accesses made to the copy of the resources located in the second chip bonded on top, even when the second chip is not present.

Circuits to ensure consistent behaviour between accesses to conventional system resources and accesses to alternative resources such as overlay memories are often used within SoC devices containing development resources.

The first and second semiconductor chips of the invention can be formed using the same mask sets so that the inner part of the first semiconductor chip is identical to the second semiconductor chip.

The electronic circuit elements of the first and second semiconductor chips can comprise memory circuits and/or processor circuits and/or debug circuits.

Each chip can comprise interface circuitry for the first set of input terminals and interface circuitry for the second set of output terminals.

The first connection terminals of the first semiconductor chip can include a sub-set of terminals for providing external connection to the second semiconductor chip. In this case, the sub-set of terminals can be connected to an input/output interface of the device additional to the second connection terminals of the first semiconductor chip.

The invention also provides a method of manufacturing a semiconductor device comprising:

manufacturing first and second semiconductor chips, each comprising electronic circuit elements located at an inner part of the chip, first connection terminals located on an upper surface of the inner part of the chip and second connection terminals located at a peripheral part of the chip;

removing the second connection terminals of the second semiconductor chip;

mounting the first and second semiconductor chips one on top of the other to form the device; connecting together the first and second semiconductor chips by the first connection terminals, the second connection terminals of the first semiconductor chip providing external connections to the device.

The first and second chips may be identical or they may be different, for example forming part of a set of related chips for a product range.

According to a second aspect of the invention, there is provided a set of semiconductor chips, comprising at least two different types of semiconductor chip, each type comprising:

electronic circuit elements located at an inner part of the chip, first connection terminals located on an upper surface of the inner part of the chip and second connection terminals located at a peripheral part of the chip,
wherein the peripheral part of each chip is adapted to be removable to enable the connection of one chip without the peripheral part removed to another chip with the peripheral part removed to form a multiple chip semiconductor device, the connection being by the first connection terminals of the chips, and wherein the second connection terminals of the one semiconductor chip provide external connections to the device.

This aspect provides a further extension of the invention, by which the extra inner bonding pads are provided on every design produced as part of a product range at a consistent location, such as at the centre of the chip, as a means of attaching any one of a plurality of system chips from a product range to any one other of the plurality of chips in the product range. The chip having its pad ring removed should allow connection to the pads in the pad ring of the complete SoC part.

This enables different resources to be added to separate SoCs as a prototyping means. For example, automotive controllers contain significant processing and timer resources, while infotainment controllers may have a USB interface. The attachment of an infotainment SoC to an automotive SoC could be used as a prototype for a new SoC device that has not yet been designed or produced.

As the resources are all then part of the same product range, they are likely to be compatible. This method when used for prototyping could significantly reduce product time to market as the SiP device could be used to emulate the new SoC long before first silicon, let alone first working silicon. One complication of bonding a second chip on top of the complete chip is that there may be insufficient space to place further bonding pads within the main pad ring on the chip surface to attach sender and receiver cells required to implement a high speed off chip communication interface such as that desired for development purposes. This can be overcome by placing extra bonding pads in the main pad ring which will not be used in the conventional SoC. The extra pads in the pad ring are then used as part of an electrical connection between a debug support interface integrated in every chip produced and sender and receiver cells located on top of the package. Examples of sender and receiver cells include lasers and photodiodes respectively.

In all the possible embodiments there exists an interface circuit within each chip that has been realised such that when one copy of a system chip can communicate with a second copy of the same system chip when the second copy is flipped on top of the first copy of the chip.

### BRIEF DESCRIPTION OF THE DRAWINGS

Specific embodiments of the invention will now be described by way of example with reference to the accompanying drawings in which:

FIG. 1 shows a single chip forming part of the semiconductor device of the invention and having input and output bonding pads located within a peripheral ring of external bonding pads;

FIG. 2 shows a complete semiconductor device of the invention;

FIG. 3 shows a second chip forming part of the semiconductor device of the invention with the pad ring area that will be removed to enable bonding to another copy of the system chip;

FIG. 4 shows the complete device of the invention in side view with the device mounted within semiconductor device packaging; and

FIG. 5 shows a second embodiment of the complete device of the invention in side view.

### DETAILED DESCRIPTION

The invention provides a semiconductor device comprising first and second semiconductor chips, each comprising electronic circuit elements located at an inner part of the chip, first connection terminals located on an upper surface of the inner part of the chip and second connection terminals located at a peripheral part of the chip. One chip has the peripheral connections removed, and it is mounted (up-side down) on the other chip connected together by the first connection terminals. The second connection terminals of the first semiconductor chip provide external connections to the device.

The invention provides a device which increases the resources of a first system chip design without the requirement of designing a second semiconductor device specifically for attachment to said first design.

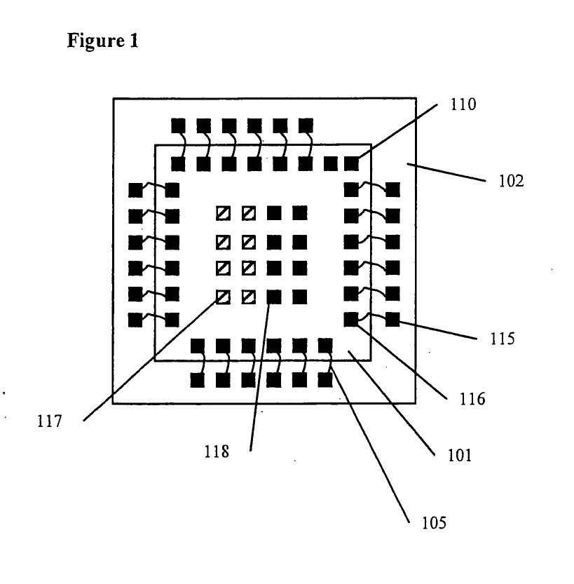

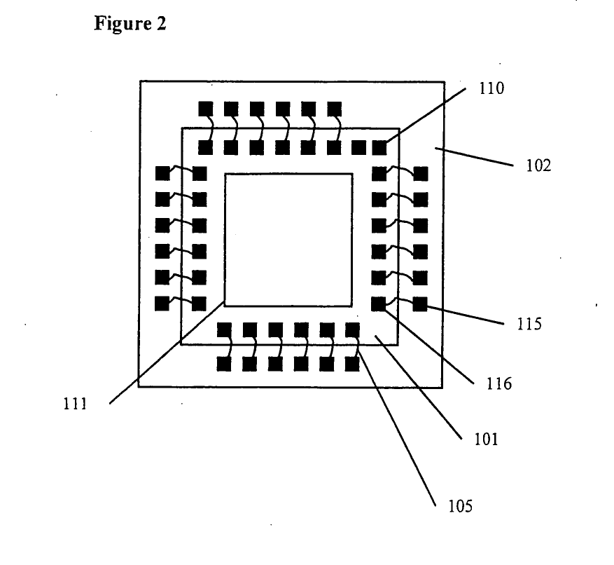

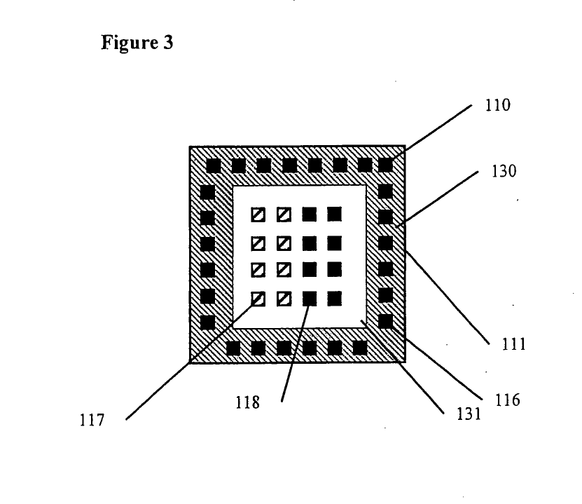

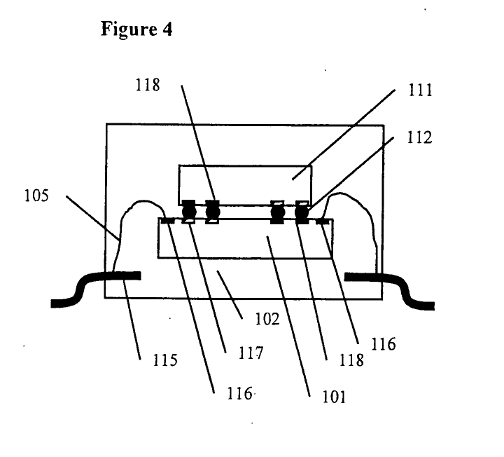

The invention provides a device comprising two chips mounted one on top of the other. FIG. 1 shows the lower chip 101 alone and shows the connections 105 from the lower chip 101 to bonding pads 115 of the device package 102. FIG. 2 shows in plan view the complete device having the lower chip 101 and upper chip 111. FIG. 3 shows the upper chip 111 alone, and FIG. 4 shows in side view the complete device.

In more detail, and referring to FIGS. 1 to 4, the device of the invention comprises a first integrated circuit assembly refereed to herein as a system chip 101 in which an outer arrangement of connection terminals 116 is for connecting the integrated circuit to other components of the system via the device package arrangement 102, its bonding pads 115 and any bonding wires or similar 105. An interface circuit integrated into each system chip allows communication to take place between the first system chip 101 and a second system chip 111 that has had its size reduce by removal of the integrated circuit periphery 130, to leave only chosen system and development circuits 131 such as memories, processors, peripherals, debug circuits or similar.

In most embodiments the removed circuits will include the outer arrangement of connection terminals 116. The communications between the first system chip 101 and the second system chip 111 take place using an inner arrangement of connection terminals which includes an arrangement of signal or power inputs 117 and an arrangement of signal or power outputs 118. In the input arrangement 117 and output arrangement 118 are positioned such that when both the first semiconductor device 101 and the second semiconductor device 111 include both parts of the second arrangement of connection terminals, that transposing or ‘flipping’ the second semiconductor device 111 on top of the first semiconductor device permits alignment of the input arrangement 117 on one semiconductor device to the output arrangement 118 on the other semiconductor device and vice versa.

The electrical connections between the input arrangement 117 and the output arrangement is made using flip-chip bonding using solder balls 112 or similar method.

In the preferred embodiment, the first system chip 101 and the second system chip 111 are both identical realisations of the same design which has been produced using the same integration process and integration mask set.

In a second alternative embodiment, the first system chip 101 and the second system chip 111 are realisations of different integrated circuit designs but include identical arrangements of inner connection terminals such that when aligned the input arrangements 117 and output arrangements 118 of the first system chip can be aligned with the input arrangement 117 and output arrangement of the second system chip. This allows system chip resources to be chosen based on the system chips available in a product range, this supports the realisation of an enhanced or prototype system chip.

The product range would typically be the SoCs provided by one semiconductor company. Typically, they may offer system on chips for different applications e.g. industrial control, multimedia/information/entertainment, engine control. Each chip has slightly different circuits, although they typically all contain a processor, memory and peripheral units (e.g. timers, communications units such as USB, analogue to digital conversion). The processors may differ between products but are generally similar e.g. revised or faster versions in newer parts. The main processor may not be the same, which will be increasingly the case as devices have multiple heterogeneous processors.

Joining different controllers in the different chips can be used to get the mix of resources required to prototype a chip that does not yet exist but has been requested by customers.

This approach enables low volume product developers or those wanting prototypes to select resources based on what is already available. Existing availability gives low cost and low design time. The chip companies can already reuse parts of designs to build new chips, and this invention enables not only the reuse of the design but the physical circuit.

The product range developed in this way will be made from compatible designs or compatible circuits, namely they will be designed to work together and connect together as modules and cores.

In a third embodiment, the circuits integrated within the first system chip 101 and or second system chip 111 to drive the input arrangement 117 and output arrangement 118 include circuits that are configurable to make the internal delay in accessing a specific resources such as memory or similar within a single system chip, specifically the first system chip 101, very similar to the delay in accessing the second copy of the said resource located in another system; chip but principally the second system chip 111.

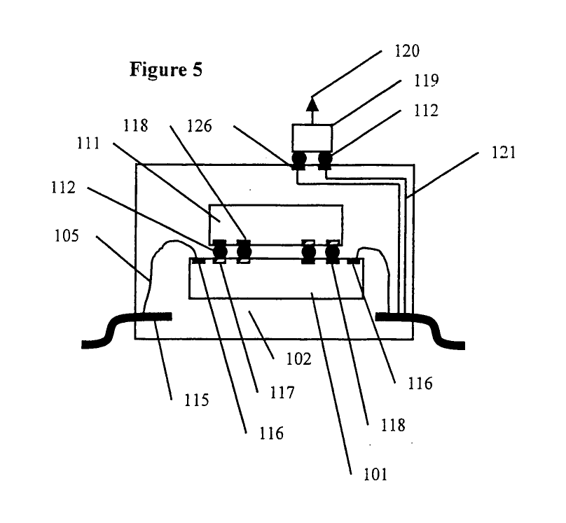

FIG. 5 shows a fourth embodiment in which the first arrangement of connection terminals 116 includes additional connection terminals 110 not used in the mass produced system chip that can be used to make additional connections with the second system chip 111 via the first system chip 101. This may include power or signal connections for the purpose of accessing additional system resources, development resources or peripheral connections.

These additional connection terminals 110 are then connected to using bonding wires 105 and routed through the device package arrangement 102 using a connection arrangement 121 to further connection terminals 126 placed on the outside of the device package arrangement 102. The connection terminals 126 could then optionally be to flip-chip bond using solder balls 112 sender and or receiver cells such as vertical cavity surface emitting lasers 119 or photo detectors or similar as a means of converting from electrical signals to and or from optical signals 120 or similar.

The invention enables extra resources of every type to be provided on the SoC, but with the same input output interface. The invention enables realisation of more complex SoCs for example for aerospace prototypes.

The invention can be used as a rapid prototyping system for enhancement of an SoC family or for an SoC with custom options. Significant calibration overlays are made possible.

The interface between the chips can be used to provide access to non volatile memory devices for debug and profiling data. An additional use of the second SoC is as a consistency checking platform, which may be required for example for automotive systems or safety critical systems or similar. A further possible use of the second SoC is for preproduction bug monitoring to help find behavioural anomalies.

The invention can be implemented using existing technology, using a production SoC mask set.

Various modifications will be apparent to those skilled in the art.

1. A semiconductor device comprising:
a first semiconductor chip comprising electronic circuit elements located at an inner part of the chip, first connection terminals located on an upper surface of the inner part of the chip and second connection terminals located at a peripheral part of the chip; and
a second semiconductor chip comprising electronic circuit elements corresponding to those of the first semiconductor chip, and first connection terminals located on an upper surface of the chip corresponding to the first connection terminals of the first semiconductor chip,
wherein the first and second semiconductor chips are mounted one on top of the other to form the device, connected together by the first connection terminals of the first and second semiconductor chips, and wherein the second connection terminals of the first semiconductor chip provide external connections to the device and wherein the inner part of the first semiconductor chip is identical to the second semiconductor chip.

2. A device as claimed in claim 1, wherein the first and second semiconductor chips are formed using the same mask sets.

3. A device as claimed in any preceding claim, wherein the first connection terminals of the first and second semiconductor chips comprise bonding pads.

4. A device as claimed in any preceding claim, wherein the electronic circuit elements of the first and second semiconductor chips comprise memory circuits and/or processor circuits and/or debug circuits.

5. A device as claimed in any preceding claim, wherein the first connection terminals include a first set of input terminals and a second set of output terminals, the input terminals of one chip being connected to the output terminals of the other chip.

6. A device as claimed in claim 5, wherein the first connection terminals include power input terminals and power output terminals.

7. A device as claimed in claim 5 or 6, wherein each chip comprises interface circuitry for the first set of input terminals and interface circuitry for the second set of output terminals.

8. A device as claimed in claim 7, wherein the interface circuitry is adapted to provide substantially identical delay for communication between components on the first chip as between components on the first and second chip.

9. A device as claimed in any preceding claim, wherein the first connection terminals of the first semiconductor chip include a sub-set of terminals for providing external connection to the second semiconductor chip.

10. A device as claimed in claim 9, wherein the sub-set of terminals are connected to an input/output interface of the device additional to the second connection terminals of the first semiconductor chip.

11. A device as claimed in claim 10, wherein the input/output interface is provided on top of the device.

12. A method of manufacturing a semiconductor device comprising:
manufacturing first and second semiconductor chips, each comprising electronic circuit elements located at an inner part of the chip, first connection terminals located on an upper surface of the inner part of the chip and second connection terminals located at a peripheral part of the chip;
removing the second connection terminals of the second semiconductor chip;
mounting the first and second semiconductor chips one on top of the other to form the device;
connecting together the first and second semiconductor chips by the first connection terminals, the second connection terminals of the first semiconductor chip providing external connections to the device.

13. A method as claimed in claim 12, wherein the first and second chips are identical.

14. A method as claimed inn-claim 12, wherein the first and second chips are different.

15. A method as claimed in claim 14, wherein the first and second chips form part of a set of related chips for a product range.

16. A method as claimed in any one of claims 12 to 15, wherein the first connection terminals include a first set of input terminals and a second set of output terminals, and wherein connecting together the first and second semiconductor chips comprises connecting the input terminals of one chip to the output terminals of the other chip.

17. A method as claimed in any one of claims 12 to 16, wherein the first connection terminals of the first semiconductor chip include a sub-set of terminals for providing external connection to the second semiconductor chip, and wherein the method further comprises connecting the sub-set of terminals to an input/output interface of the device which is additional to the second connection terminals of the first semiconductor chip.

18. A set of semiconductor chips, comprising at least two different types of semiconductor chip, each type comprising:
electronic circuit elements located at an inner part of the chip, first connection terminals located on an upper surface of the inner part of the chip and second connection terminals located at a peripheral part of the chip,
wherein the peripheral part of each chip is adapted to be removable to enable the connection of one chip without the peripheral part removed to another chip with the peripheral part removed to form a multiple chip semiconductor device, the connection being by the first connection terminals of the chips, and wherein the second connection terminals of the one semiconductor chip provide external connections to the device.
